(19) United States
(12) Patent Application Publication
(10) Pub. No.: US 2004/0246675 A1
(43) Pub. Date: Dec. 9, 2004

(54) Instrumentation console for personal computers

(76) Inventor: Jen-Cheng Lin, Chung-Ho City (TW)

Correspondence Address: DELLETT AND WALTERS, P. O. BOX 2786, PORTLAND, OR, 97208-2786, US

(21) Appl. No.: 10/456,182

(22) Filed: Jun. 5, 2003

(51) Int. Cl. H05K 7/14

(52) U.S. Cl. 361/686; 361/687; 361/681

(57) ABSTRACT

An instrumentation console for personal computers is provided. The instrumentation console module is formed by a display panel, a circuit board (10) embedded with a plurality of control circuits, and a bracket (100). The control circuits through the connector ports (102-105) are coupled to the monitored internal components and monitoring devices such as cooling fans (19), audio output (21) and temperature sensors (14) for collecting essential operation data with respect to the host computer (20). The control circuits of the circuit board (10) collect the signals, and then output them to the visual indicators (11-13) on the display panel after appropriate signal conversion, instantly reflecting the operating conditions of the host computer (20) for early diagnosis of problems to prevent major problems from developing later.

### BACKGROUND OF THE INVENTION

1. Field of the Invention

The present invention relates to an instrumentation console for personal computers, in particular to a console module that can convert the essential operation data of a host computer to visual indicators for early diagnosis of potential problem areas.

2. Description of Related Arts

In a highly competitive business society, most people have to make use of the data processing equipment to improve their productivity. The widespread use of personal computers and networking technology has also stimulated the rapid development in computer software for a variety of applications. Hardware manufacturers are relentlessly trying to improve the processing capability and functionality of present day computers with faster CPUs and new peripheral devices. However, these extra power and speed requirements will add to the existing workload and power consumption of the computer. The rising temperature during the data processing has become a critical issue for designers of high performance computers. To cope with the increased sophistication in the hardware design, appropriate means are devised to cool down the CPU and other important internal components to ensure the smooth operation of the computer.

The operating temperature of essential components in the computer such as the motherboard, CPU, and power supply unit has to bc appropriately monitored and controlled. For a CPU embedded in a motherboard, a heat sink and CPU fan are often used to cool down the operating temperature during high-speed data processing; the power supply unit usually has a cooling fan built in. The ambient temperature inside the casing can be suitably controlled by installing one or two additional ventilation fans on the back or front panel or both.

The next task is to follow up and check on the operating conditions of these internal components and monitoring devices such as the operating temperature of the CPU and the motherboard, and the turning speed of the fans to make sure these components and monitoring devices are operating in the normal conditions.

However, most conventional computer casings do not provide an instrumentation console for monitoring this essential operation data. It is therefore difficult for users to obtain first hand information with regard to the operating condition of their computers. The working computer will reveal the hard fact only when some hardware problems appear or when the system goes down.

### SUMMARY OF THE INVENTION

The main object of the present invention is to provide a hardware console module for installation in a host computer. The control circuits in the console is capable of generating visual indicators reflecting the essential operation data in the host computers for early diagnosis of potential trouble spots.

The hardware installation of the instrumentation console in accordance with the present invention is to set up at least one set of instrument console on the front panel of the host computer, depending on the user applications. The structure of the console module comprises a display panel, a circuit board and a bracket. The circuit board has a plurality of connector ports and a power terminal connecting to the inputs of the respective control circuits embedded in the circuit board for establishing the physical link with monitored internal components and monitoring devices such as cooling fans, audio line output and temperature sensors disposed at several check points.

The outputs of the instrumentation console are connected to respective visual indicators disposed on the display panel for displaying the essential operation data of the host computer. Output signals representing the essential operation data of the host computer are collected by the monitored internal components and monitoring devices. After signal conversion, these signals are output to respective visual indicators for monitoring and early diagnosis of potential problems in the host computer.

The above-mentioned instrumentation console in accordance with the invention includes a voltage-level detection circuit, wherein the input is connected to the power output for the cooling fan, and the input is also coupled to a power output terminals which is simultaneously connected to the cooling fan for providing the operating voltage.

The voltage-level detection circuit in accordance with the invention is formed by a variable voltage regulator. The variable voltage regulator is used for stabilizing the power supply to the cooling fan, and the output is connected to one of the visual indicators reflecting the voltage variations indicative of the operating conditions of the cooling fan.

The instrumentation console in accordance with the invention also includes a sound wave conversion circuit, wherein the input is connected to the audio output (line out) of the host computer to collect the audio output signals. After collection of the audio signals, the signals are converted and output to the respective visual indicator indicative of the output power from the audio line.

The instrumentation console in accordance with the invention also includes a temperature signal conversion circuit, wherein the input of the temperature signal conversion circuit is connected to a temperature sensor attached on an internal component to monitor the operating temperature thereon, and the output is connected to the respective visual indicator indicative of the operating temperature of the internal component after conversion of the temperature signals.

The above-mentioned instrumentation console is designed for installation onto a 5.25″ drive bay on the front panel of the computer casing. The overall size of the instrumentation console module is equivalent to a standard CD-R or hard disk drive for any computer casing.

The features and structure of the present invention will be more clearly understood when taken in conjunction with the accompanying drawings.

### BRIEF DESCRIPTION OF THE DRAWINGS

FIG. 1 is a perspective diagram of the present invention;

FIGS. 2A-2C are a detailed circuit diagram of the instrumentation console;

FIG. 3 is a perspective diagram of a preferred embodiment of the invention; and

FIG. 4 is a user installation diagram of the instrumentation console module being mounted into a standard drive slot in a computer casing.

### DETAILED DESCRIPTION OF THE PREFERRED EMBODIMENT

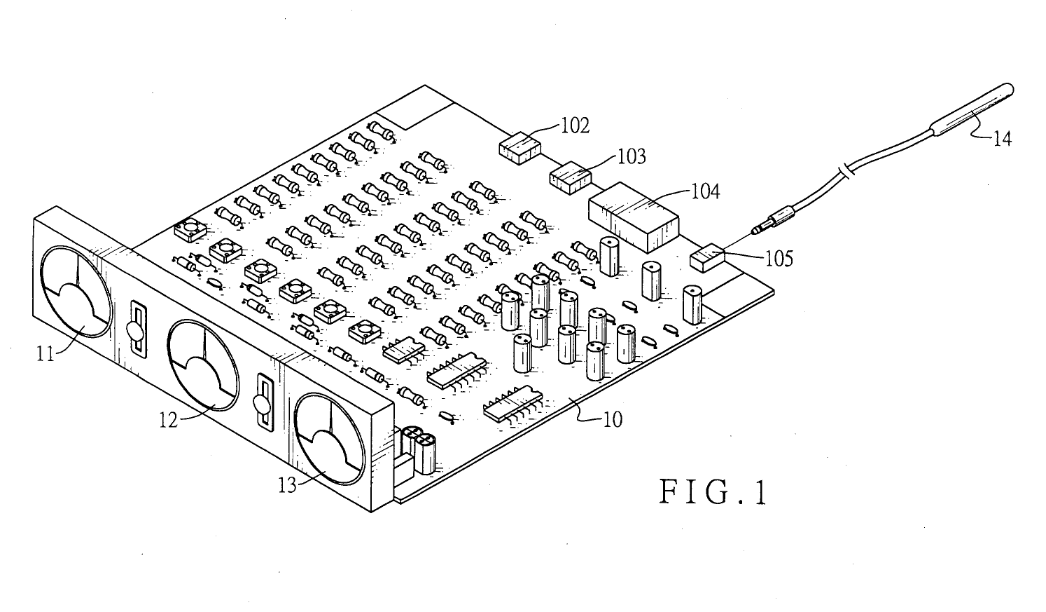

The present invention provides a hardware instrumentation console for installation on a host computer or for direct connection to the host computer, which is used to monitor the essential operation data in the host computer with a user-friendly interface. In accordance with one preferred embodiment of the invention, the hardware installation includes at least one set of instrumentation console module as shown in FIG. 1. Each instrumentation console module comprises a display panel (not numbered), a circuit board (10) and a bracket (100), wherein the display panel is erected from the front end of the circuit board (10) having a plurality of visual indicators (11-13) in front, and the circuit board (10) has a plurality of control circuits built in (to be explained in the following paragraph) for gathering essential operation data from components inside the host computer (20). The circuit board (10) also has a plurality of connector ports (102-105) at the back end for connecting to the monitored internal components and monitoring devices such as a cooling fan (19), an audio output (21) and a temperature sensor (14).

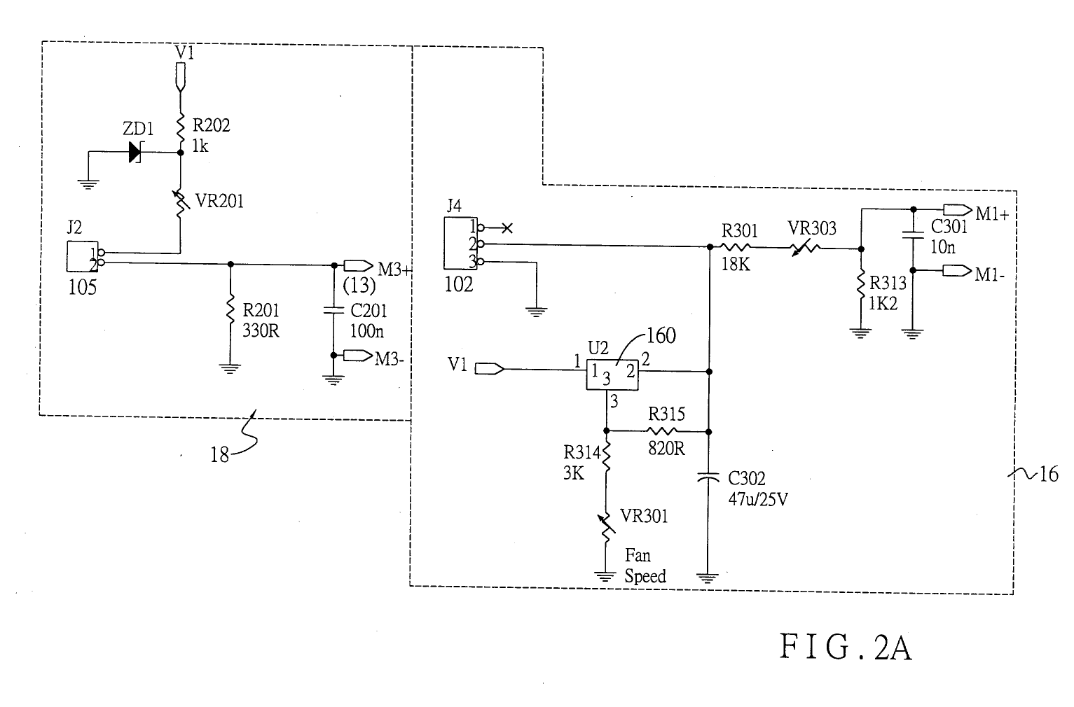

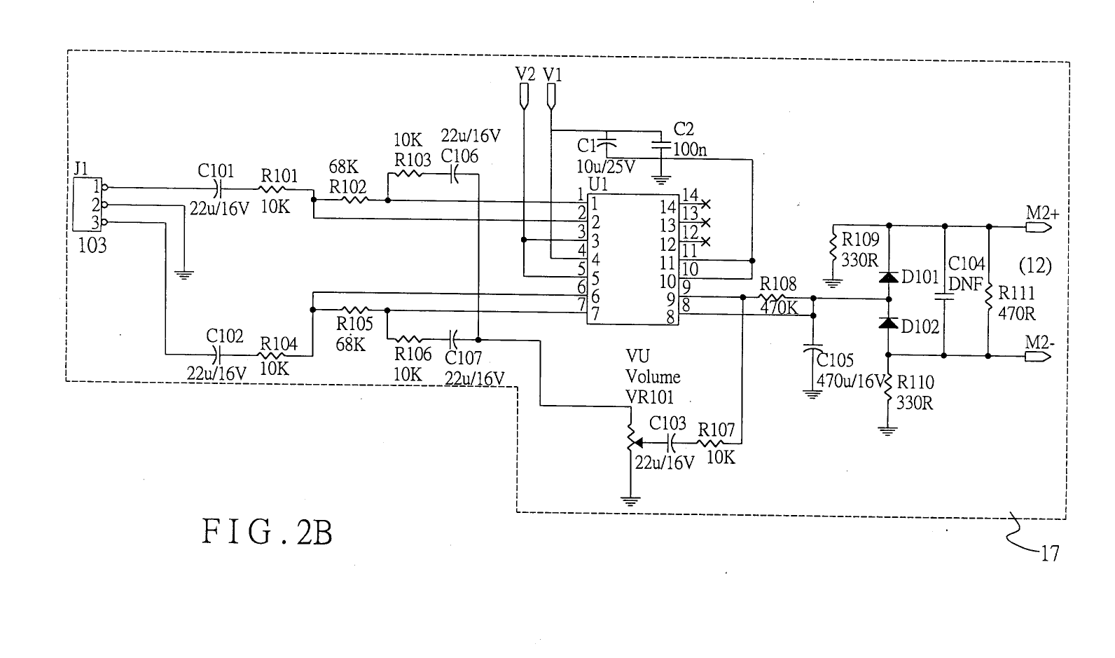

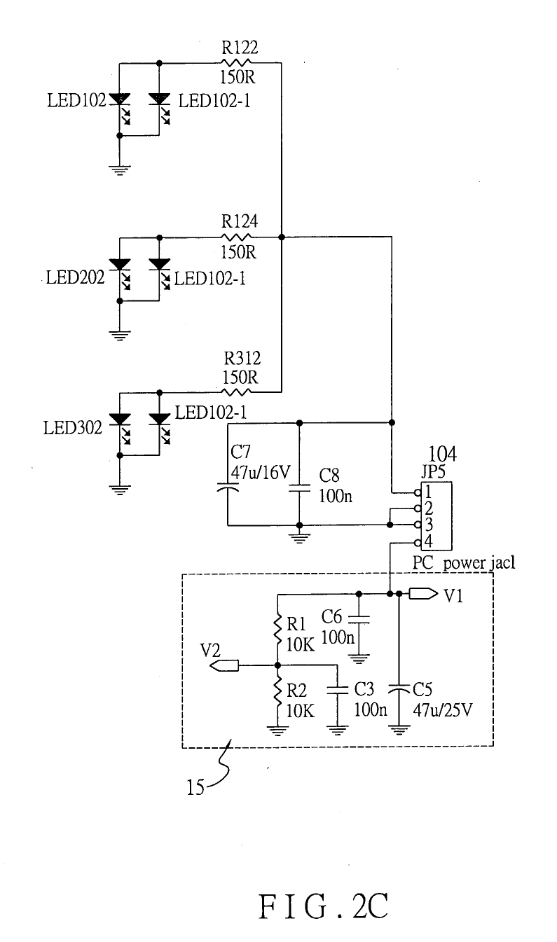

In accordance with one preferred embodiment of the present invention, as shown in FIGS. 2A-2C, the instrumentation console has three sets of control circuits built in: a voltage-level detection circuit (16), a sound wave conversion circuit (17), and a temperature signal conversion circuit (18) (although the configuration could be modified to suit the specific application needs). The input terminals and the power terminal are respectively connected to the connector ports (102-105) for establishing physical links with monitored internal components and monitoring devices such as the cooling fan (19), audio output (21) and temperature sensor (14), and the outputs of the control circuits are respectively connected to the corresponding visual indicators (11-13). After the signals are collected from the monitored internal components and monitoring devices, they are converted to a required format and then output to the corresponding visual indicators (11-13) reflecting the essential operation data from the host computer (20).

In FIGS. 2A-2C, the circuit diagram shows the structure of the three control circuits: a power converter (15), a voltage-level detection circuit (16), a sound wave conversion circuit (17) and a temperature signal conversion circuit (18). The input of the power converter (15) is connected to the connector port (104) for receiving the power input, and the outputs (V1, V2) provide the operating voltage for the above mentioned control circuits through two shunt resistors R1, R2.

The voltage-level detection circuit (16) is formed by a variable voltage regulator (160), wherein the input terminal is connected to the power output V1 of the power converter (15) for receiving the power for the cooling fan (not shown), and the output terminal is connected to the connector port (102) which in turn is connected to the cooling fan (19) providing the power supply;

The variable voltage regulator (160) is used to stabilize the power drawn from the power output V1, and the output is connected to the cooling fan (19) and also to the visual indicator (11) to reflect the voltage variations indicative of the operating conditions of the cooling fan (19).

The sound wave conversion circuit (17) is formed by an operational amplifier (U1), wherein the input is connected to the output of audio output (line out) (as the sound card is built into the circuit board) to collect the audio signals, and the output is connected to respective visual indicator (12) after signal conversion by the sound wave conversion circuit (17) indicative of the output power of the audio line.

The temperature signal conversion circuit (18) is formed by a power circuit and a resistor, wherein the power circuit is formed by a resistor R202, a variable resistor VR201, and a Zener diode ZD1, and the power input is drawn from the power converter (15) through the power output V1., and the output is connected to the connector port (105) through which it provides the operating voltage for the temperature sensor (14) (as shown in FIG. 1) The connector port (105) through R201 is connected to the visual indicator (13) for reflecting the voltage variations on the temperature sensor (14) indicative of the temperature level detected by the sensor at a specific monitoring location.

A plurality of temperature sensors (14) is placed at several check points around the monitored internal components on the circuit board for monitoring the operating temperature of the internal components in the host computer (20).

For the sake of user convenience, the visual indicators (11-13) in accordance with the present invention are adapted to use pointer-type dial meters to indicate the measured operation data, but the signal processing can be done either by analog or digital means.

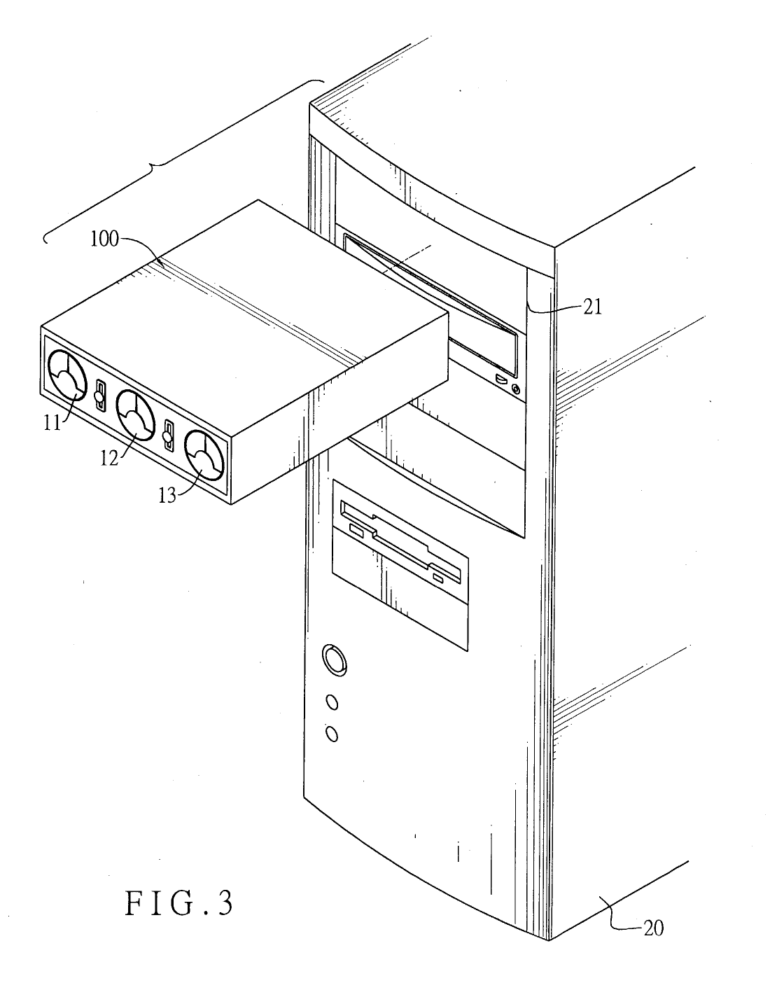

The above illustration gave the basic architecture of the preferred embodiment of the invention, in FIG. 3, The user installation diagram shows the instrumentation console for personal computers being inserted into a standard drive bay in the computer casing of a host computer. The console module is set in a bracket (100) compatible with a standard 5.25″ drive bay in a computer casing, and three visual indicators (11-13) are installed on the display panel to be mounted on the front of the computer casing.

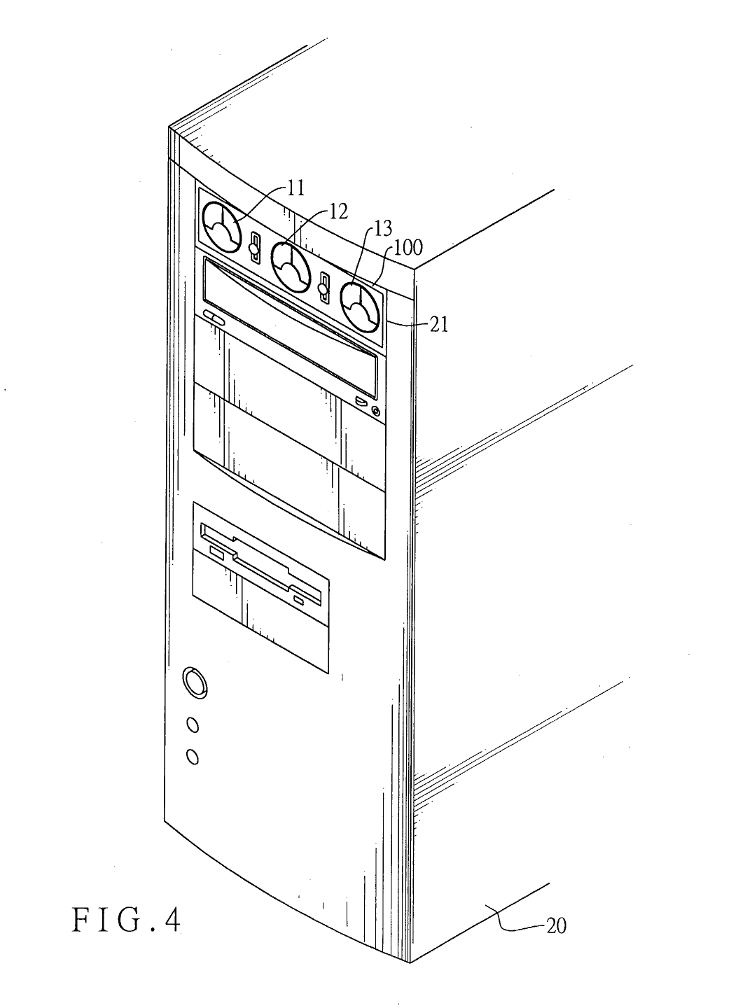

In FIG. 4, the instrumentation console module can be installed on the host computer (20) through the optional drive bay using the bracket (100), such that the user of the host computer (20) can be instantly informed of the essential operation data from the host computer (20) through the visual indicators (11-13) indicative of the operating conditions of the monitored internal components in the host computer (20), such that the user is able to discover early signs of problems in the host computer (20) to avoid major problems later.

The foregoing description of the preferred embodiments of the present invention is intended to be illustrative only and, under no circumstances, should the scope of the present invention be so restricted.

What is claimed is:

1. An instrumentation console for personal computers comprising a display panel (not numbered) and a circuit board (10), wherein
inputs of the circuit board (10) are coupled to a plurality of connector ports (102-105) and a power terminal for collecting essential operation data from monitored internal components and monitoring devices mounted onto a host computer (20); and
outputs of the circuit board (10) are respectively connected to visual indicators (11-13) on the display panel, for displaying the essential operation data collected from internal components and monitoring devices indicative of operating conditions inside the host computer (20).

2. The instrumentation console for personal computers as claimed in claim 1, wherein the circuit board (10) on the instrumentation console has a built in voltage-level detection circuit (16), wherein an input is connected to one of two power outputs of a power converter (15) for drawing the operating power, and an output is connected to a cooling fan through one of the connector ports (102) providing operating voltage for the cooling fan;
the voltage-level detection circuit formed by a variable voltage regulator used for stabilizing the power supply, and the output is connected to one of the visual indicators (11) reflecting the voltage variations on the output power of the cooling fan.

3. The instrumentation console for personal computers as claimed in claim 1, wherein the circuit board (10) in the instrumentation console further has a sound wave conversion circuit (17), wherein the input is connected to the audio output of the host computer (20) to collect the audio output signals, and the output of the sound wave conversion circuit (17) is connected to one of the visual indicators (12) reflecting the output power collected from the audio signal line.

4. The instrumentation console for personal computers as claimed in claim 3, wherein the sound wave conversion circuit (17) is formed by an operational amplifier.

5. The instrumentation console for personal computers as claimed in claim 1, wherein the circuit board (10) on the instrumentation console further has a temperature signal conversion circuit (18), wherein the input is connected to a temperature sensor (14), and the output is connected to one of the visual indicators (13) reflecting the operating temperature collected by the temperature sensor over an internal component being monitored.

6. The instrumentation console for personal computers as claimed in claim 5, wherein the temperature signal conversion circuit (18) is formed by a power circuit and a resistor, wherein the power circuit is formed by a resistor, a variable resistor, and a Zener diode, and the output of the power circuit provides the operating voltage for the temperature sensor (14) through the connector port (105), and the output through the resistor is connected to the visual indicator (13).

7. The instrumentation console for personal computers as claimed in claim 1, wherein the circuit board (10) on the instrumentation console further has a power converter (15), wherein the input is connected to one of the connector ports (102-105), and the outputs through two shunt resistors are connected to at least one control circuit embedded in the circuit board (10) providing the operating voltage for the embedded control circuits.

8. The instrumentation console for personal computers as claimed in claim 2, wherein the circuit board (10) on the instrumentation console further has a power converter (15), wherein the input is connected to one of the connector ports (102-105), and the outputs through two shunt resistors are connected to at least one control circuit embedded in the circuit board (10) providing the operating voltage for the embedded control circuits.

9. The instrumentation console for personal computers as claimed in claim 3, wherein the circuit board (10) on the instrumentation console further has a power converter (15), wherein the input is connected to one of the connector ports (102-105), and the outputs through two shunt resistors are connected to at least one control circuit embedded in the circuit board (10) providing the operating voltage for the embedded control circuits.

10. The instrumentation console for personal computers as claimed in claim 4, wherein the circuit board (10) on the instrumentation console further has a power converter (15), wherein the circuit board (10) on the instrumentation console further has a power converter (15), wherein the input is connected to one of the connector ports (102-105), and the outputs through two shunt resistors are connected to at least one control circuit embedded in the circuit board (10) providing the operating voltage for the embedded control circuits.

11. The instrumentation console for personal computers as claimed in claim 5, wherein the circuit board (10) on the instrumentation console further has a power converter (15), wherein the circuit board (10) on the instrumentation console further has a power converter (15), wherein the input is connected to one of the connector ports (102-105), and the outputs through two shunt resistors are connected to at least one control circuit embedded in the circuit board (10) providing the operating voltage for the embedded control circuits.

12. The instrumentation console for personal computers as claimed in claim 6, wherein the circuit board (10) on the instrumentation console further has a power converter (15), wherein the input is connected to one of the connector ports (102-105), and the output through the shunt resistor provides at least one set of power outputs for providing the power supply to at least one control circuit embedded in the circuit board (10).

13. The instrumentation console for personal computers as claimed in claim 7, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

14. The instrumentation console for personal computers as claimed in claim 8, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

15. The instrumentation console for personal computers as claimed in claim 9, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

16. The instrumentation console for personal computers as claimed in claim 10, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

17. The instrumentation console for personal computers as claimed in claim 11, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

18. The instrumentation console for personal computers as claimed in claim 12, wherein the circuit board (10) is mounted onto a bracket (100), and the visual indicators (11-13) are installed on a display panel erecting from a front end of the circuit board (10), such that the bracket (100) is able to fit in a 5.25″ drive bay in a standard computer casing.

19. The instrumentation console for personal computers as claimed in claim 7, wherein the visual indicator (11-13) is adapted to use a pointer-type dial meter.

20. The instrumentation console for personal computers as claimed in claim 8, wherein the visual indicator (11-13) is adapted to use a pointer-type dial meter.
